(19) United States
(12) Patent Application Publication
(10) Pub. No.: US 2015/0179874 A1
(43) Pub. Date: Jun. 25, 2015

(54) LIGHT EMITTING DIODE STRUCTURE

(71) Applicant: Yu-Chu Li, Tainan City (TW)

(72) Inventor: Yu-Chu Li, Tainan City (TW)

(73) Assignee: GENESIS PHOTONICS INC., Tainan City (TW)

(21) Appl. No.: 14/257,012

(22) Filed: Apr. 21, 2014

(30) Foreign Application Priority Data
Dec. 25, 2013 (TW) 102148234

(51) Int. Cl. H01L 33/00

(52) U.S. Cl. CPC H01L 33/0025

(57) ABSTRACT

A light emitting diode (LED) structure includes a substrate, a N-type semiconductor layer, a light emitting layer and a P-type semiconductor layer. The N-type semiconductor layer is disposed on the substrate. The light emitting layer is adapted to emit a light with dominant wavelength between 365 nm and 490 nm and disposed on the N-type semiconductor layer. The P-type semiconductor layer is disposed on the blue light emitting layer and includes a P—AlGaN layer. A thickness of the P—AlGaN layer is more than 85% a thickness of the P-type semiconductor layer.

### CROSS-REFERENCE TO RELATED APPLICATION

This application claims the priority benefit of Taiwan application serial no. 102148234, filed on Dec. 25, 2013. The entirety of the above-mentioned patent application is hereby incorporated by reference herein and made a part of this specification.

### BACKGROUND OF THE INVENTION

1. Field of the Invention

The present invention relates to a semiconductor structure. More particularly, the present invention relates to a light emitting diode structure.

2. Description of Related Art

With progress in semiconductor technologies, a light emitting diode (LED) now has advantages of high luminance, low power consumption, compactness, low driving voltage, mercury free, and so forth. Therefore, the LED has been extensively applied in the field of displays and illumination. In general, an LED is fabricated by using a broad band-gap semiconductor material, such as gallium nitride (GaN) and the like. However, when the light emitting layer of the LED emits the near-ultraviolet light or the blue light, the P-type semiconductor layer fabricated by GaN will absorb the light with wavelength between about 365 nanometer (nm) to 490 nm. That is, the near-ultraviolet light and the blue light will be absorbed so as to affect the light emitting efficiency of the LED.

### SUMMARY OF THE INVENTION

The present invention provides a LED structure having good light emitting efficiency.

The LED structure of the present invention includes a substrate, an N-type semiconductor layer, a light emitting layer and a P-type semiconductor layer. The N-type semiconductor layer is disposed on the substrate. The light emitting layer is adapted to emit a light with dominant wavelength between 365 nm and 490 nm and disposed on the N-type semiconductor layer. The P-type semiconductor layer is disposed on the light emitting layer and includes a P—AlGaN layer. A thickness of the P—AlGaN layer is more than 85% a thickness of the P-type semiconductor layer.

In one embodiment of the invention, the P-type semiconductor layer is the P—AlGaN layer.

In one embodiment of the invention, the P-type semiconductor layer further includes a P—GaN layer disposed on the P—AlGaN layer. A thickness of the P—GaN layer is less than 15% the thickness of the P-type semiconductor layer.

In one embodiment of the present invention, the P—AlGaN layer includes a first P—AlGaN layer and a second P—AlGaN layer. A amount of aluminum of the first P—AlGaN layer is different from a amount of aluminum of the second P—AlGaN layer.

In one embodiment of the present invention, the first P—AlGaN layer is located between the second P—AlGaN layer and the light emitting layer, and the amount of the aluminum of the first P—AlGaN layer is greater than the amount of the aluminum of the second P—AlGaN layer.

In one embodiment of the present invention, a material of the first P—AlGaN layer is AlₓGa₁₋ₓN, and the x falls between 0.09˜0.2.

In one embodiment of the present invention, a material of the second P—AlGaN layer is Al_{y}Ga_{1-y}N, and the y falls between 0.01˜0.15.

In one embodiment of the present invention, a thickness of the second P—AlGaN layer is greater than the thickness of the first P—AlGaN layer.

In one embodiment of the present invention, a P-type dopant concentration of the first P—AlGaN layer is greater than a P-type dopant concentration of the second P—AlGaN layer.

In one embodiment of the invention, the P-type semiconductor layer further includes a P—AlInGaN layer disposed between the P—AlGaN layer and the light emitting layer.

In one embodiment of the invention, the N-type semiconductor layer is an N—GaN layer.

In one embodiment of the invention, the LED structure further includes an N-type electrode and a P-type electrode. The N-type electrode is disposed on the N-type semiconductor layer uncovered by the light emitting layer and electrically connected to the N-type semiconductor layer. The P-type electrode is disposed on the P-type semiconductor layer and electrically connected to the P-type semiconductor layer.

In one embodiment of the invention, the LED structure further includes a transparent conductive layer disposed on the P-type semiconductor layer.

In view of the above, since the thickness of the P—AlGaN layer is more than 85% the thickness of the P-type semiconductor layer according to the present invention, the near-ultraviolet light or the blue light emitted from the light emitting layer absorbed by the P-type semiconductor layer can be reduced. Therefore, the present invention provides a LED structure having good light emitting efficiency.

Several exemplary embodiments accompanied with figures are described in detail below to further describe the invention in details.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the invention.

FIG. 1 is a schematic cross-sectional view depicting a light emitting diode structure according to an embodiment of the present invention.

FIG. 2 is a schematic cross-sectional view depicting a light emitting diode structure according to another embodiment of the present invention.

FIG. 3 is a schematic cross-sectional view depicting a light emitting diode structure according to another embodiment of the present invention.

FIG. 4 is a schematic cross-sectional view depicting a light emitting diode structure according to another embodiment of the present invention.

FIG. 5 is a schematic cross-sectional view depicting a light emitting diode structure according to another embodiment of the present invention.

FIG. 6 is a schematic cross-sectional view depicting a light emitting diode structure according to another embodiment of the present invention.

### DESCRIPTION OF EMBODIMENTS

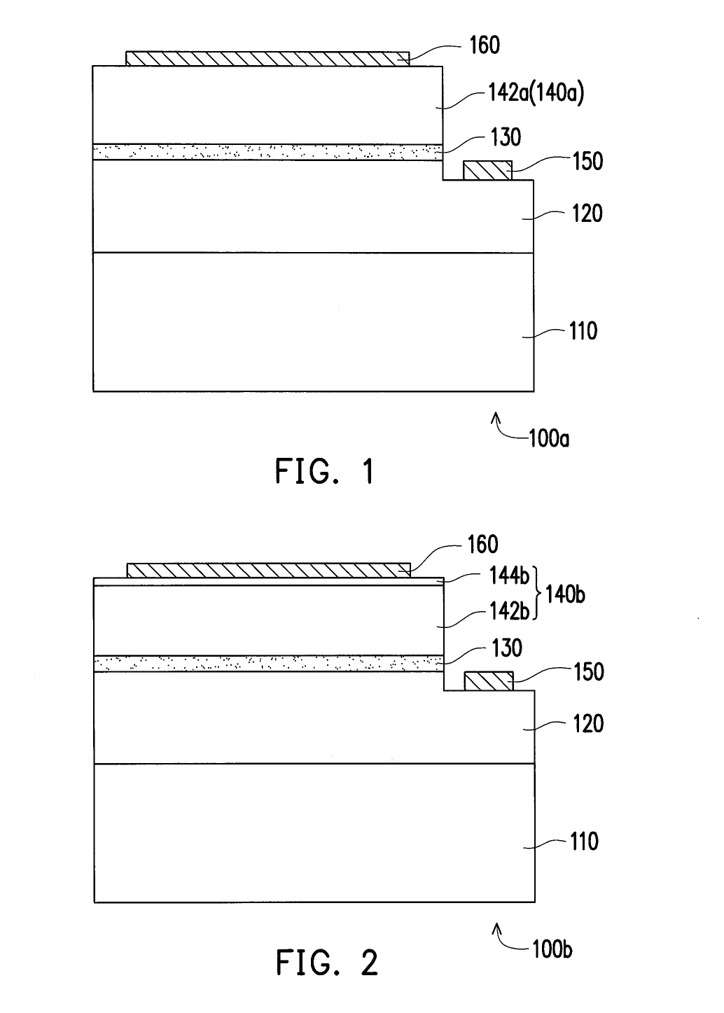

FIG. 1 is a schematic cross-sectional view depicting a light emitting diode structure according to an embodiment of the present invention. Referring to FIG. 1, in the present embodiment, the LED structure 100a includes a substrate 110, an N-type semiconductor layer 120, a light emitting layer 130 and a P-type semiconductor layer 140a. The N-type semiconductor layer 120 is disposed on the substrate 110. The light emitting layer 130 is adapted to emit a light with dominant wavelength between 365 nm and 490 nm and disposed on the N-type semiconductor layer 120. The P-type semiconductor layer 140a is disposed on the light emitting layer 130 and includes a P—AlGaN layer 142a. A thickness of the P—AlGaN layer 142a is more than 85% a thickness of the P-type semiconductor layer 140a.

In details, in the embodiment of the present invention, the substrate 110 is a sapphire substrate, for example, and the light emitting layer 130 is a quantum well structure of GaN/InGaN, however it is not limited by it. The N-type semiconductor layer 120 is located between the substrate 110 and the light emitting layer 130, and a portion of the N-type semiconductor layer 120 is exposed on the light emitting layer 130. Herein, the N-type semiconductor layer 120 is specifically an N—GaN layer. As shown in FIG. 1, the P-type semiconductor layer 140a of the present embodiment is specifically the P—AlGaN layer 142a, which means that the P-type semiconductor layer 140a is made of a single material, which is AlGaN. The thickness of the P—AlGaN layer 142a is preferably between 30 nm to 100 nm. Furthermore, in the present embodiment, the LED structure 100a further includes a N-type electrode 150 and a P-type electrode 160, wherein the N-type electrode 150 is disposed on the N-type semiconductor layer 120 uncovered by the light emitting layer 130 and electrically connected to the N-type semiconductor layer 120, and the P-type electrode 160 is disposed on the P-type semiconductor layer 140a and electrically connected to the P-type semiconductor layer 140a. Based on the arrangement of the above mentioned components, the LED structure 100a of the present embodiment is specifically a blue LED structure.

Since the P-type semiconductor layer 140a of this embodiment is specifically the P—AlGaN layer 142a, and the P—AlGaN layer 142a doesn't absorb the near-ultraviolet light or the blue light. Therefore, when the light emitting layer 130 emits light, the light can directly pass through the P-type semiconductor layer 140a without being absorbed. Therefore, the LED structure 100a of the present embodiment can have better light emitting efficiency.

It should be mentioned that the exemplary embodiments provided below adopt notations and partial content of the exemplary embodiment aforementioned. Herein, identical notations are used to denote identical or similar elements and the description of identical technology is omitted. The omitted part can be referred to the above exemplary embodiment and is not repeated hereinafter.

FIG. 2 is a schematic cross-sectional view depicting a light emitting diode structure according to another embodiment of the present invention. Referring to FIG. 2, the LED structure 100b of the present embodiment is similar to the LED structure 100a of FIG. 1, while the main difference therebetween lies in that the P-type semiconductor layer 140b of the present embodiment includes a P—AlGaN layer 142b and a P—GaN layer 144b, wherein the P—GaN layer 144b is disposed on the P—AlGaN layer 142b. More particularly, in the present embodiment, a thickness of the P—AlGaN layer 142b is more than 85% a thickness of the P-type semiconductor layer 140b. In other words, a thickness of the P—GaN layer 144b is less than 15% the thickness of the P-type semiconductor layer 140b. Preferably, the thickness of the P—GaN layer 144 is less than 10 nm.

Since the thickness of the P—AlGaN layer 142b is more than 85% of the thickness of the P-type semiconductor layer 140b of this embodiment, and the P—AlGaN layer 142b doesn't absorb the near-ultraviolet light or the blue light. According to Beer-Lambert law, when a parallel monochromatic light pass through the light-absorbing substance with homogeneous and non-scattering vertically, the degree of absorption is proportional to the concentration of the light-absorbing substance and the thickness of the light absorbing layer. In view of the above, since the thickness of the P—GaN layer 144b absorbed the blue light is far less than the thickness of the P—AlGaN layer 142b, the near-ultraviolet light or the blue light emitted from the light emitting layer 130 absorbed by the P-type semiconductor layer 140b can be reduced. Therefore, the LED structure 100b of the present embodiment can have better light emitting efficiency.

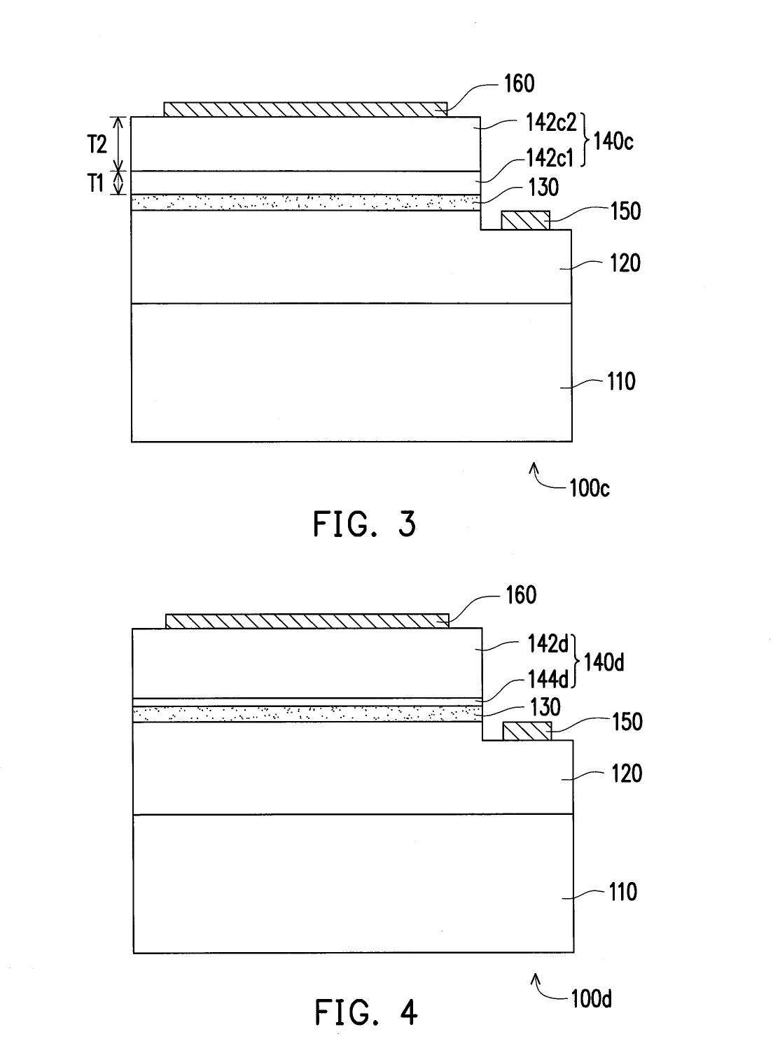

FIG. 3 is a schematic cross-sectional view depicting a light emitting diode structure according to another embodiment of the present invention. Referring to FIG. 3, the LED structure 100c of the present embodiment is similar to the LED structure 100a of FIG. 1, while the main difference therebetween lies in that the P-type semiconductor layer 140c of the present embodiment is specifically a P—AlGaN layer, wherein the P—AlGaN layer includes a first P—AlGaN layer 142c1 and a second P—AlGaN layer 142c2, and the amount of the aluminum of the first P—AlGaN layer 142c1 is different from the amount of the aluminum of the second P—AlGaN layer 142c2. Preferably, the first P—AlGaN layer 142c1 is located between the second P—AlGaN layer 142c2 and the light emitting layer 130, and the amount of the aluminum of the first P—AlGaN layer 142c1 is greater than the amount of the aluminum of the second P—AlGaN layer 142c2. Herein, a material of the first P—AlGaN layer 142c1 is AlₓGa₁₋ₓN, and the x falls between 0.09˜0.2. A material of the second P—AlGaN layer 142c2 is Al_{y}Ga_{1-y}N, and the y falls between 0.01˜0.15. A thickness T2 of the second P—AlGaN layer 142c2 is greater than a thickness T1 of the first P—AlGaN layer 142c1.

It should be noted that the P—AlGaN layer can reduce the amount of light absorption, but if the amount of aluminum of the P—AlGaN layer is too high, more epitaxial defects can cause the loss of compound carrier and the increase of the heat inside the LED structure. Furthermore, the increase of the amount of the aluminum of the P—AlGaN layer can cause another effect, which is the increase of the resistance of the P—AlGaN layer and the difficulty of fabricating the electrodes. Therefore, since the first P—AlGaN layer 142c1 near the light emitting layer 130 has high amount of aluminum, bigger band-gap and better performance of blocking the electron, the electron which didn't fall into the light emitting layer 130 can be bounced back to the light emitting layer 130, so the LED structure 100c of the present embodiment can increase the light emitting efficiency. Furthermore, the thickness T1 of the first P—AlGaN layer 142c1 is thinner, and therefore the epitaxial defect caused by high amount of aluminum can be reduced.

Furthermore, a P-type dopant concentration of the first P—AlGaN layer 142c1 in the present embodiment is greater than a P-type dopant concentration of the second P—AlGaN layer 142c2. Herein, more the P-type dopant can provide more electron holes, and the first P—AlGaN layer 142c1 is closer to the light emitting layer 130, the electrode holes is easy to enter the light emitting layer 130; therefore, through the combination of the electrode holes and the electrons in the light emitting layer 130, energy is released in a form of photon.

FIG. 4 is a schematic cross-sectional view depicting a light emitting diode structure according to another embodiment of the present invention. Referring to FIG. 4, the LED structure 100d of the present embodiment is similar to the LED structure 100a of FIG. 1, while the main difference therebetween lies in that the P-type semiconductor layer 140d of the present embodiment includes a P—AlGaN layer 142d and a P—AlInGaN layer 144d, wherein the P—AlInGaN layer 144d is disposed between the P—AlGaN layer 142d and the light emitting layer 130. In the present embodiment, the P—AlInGaN layer 144d can reduce the lattice mismatch between the P—AlGaN layer 142d and the light emitting layer 130, and the stress during the growth of the LED structure 100d can be reduced.

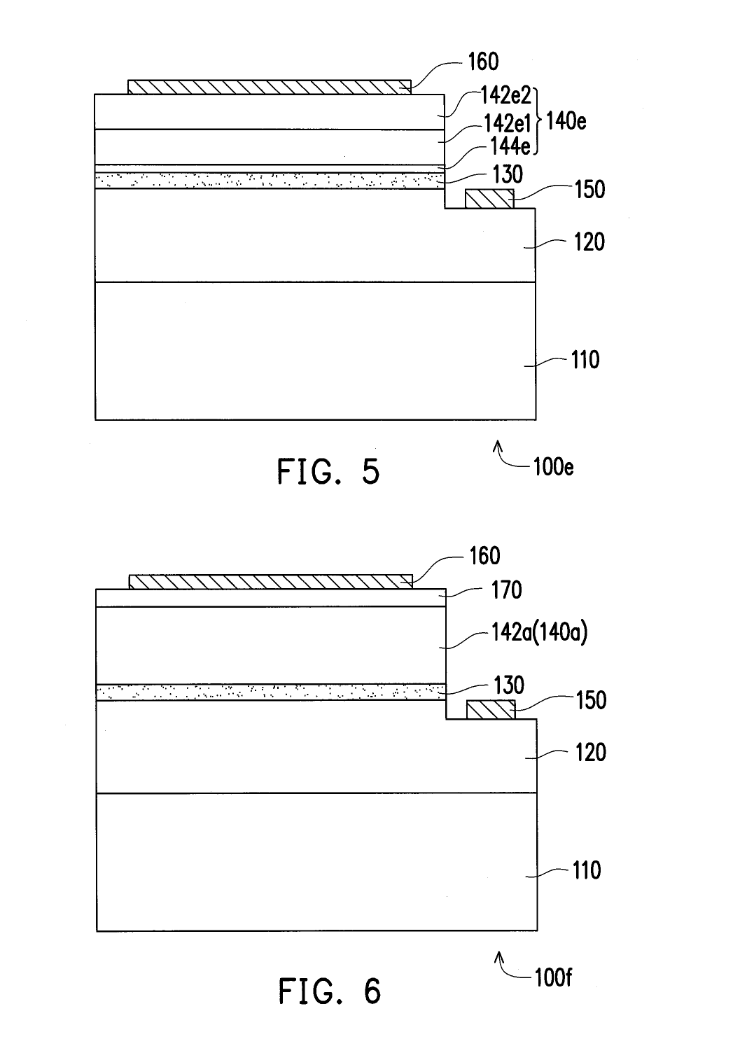

FIG. 5 is a schematic cross-sectional view depicting a light emitting diode structure according to another embodiment of the present invention. Referring to FIG. 5, the LED structure 100e of the present embodiment is similar to the LED structure 100a of FIG. 1, while the main difference therebetween lies in that the P-type semiconductor layer 140e of the present embodiment includes a first P—AlGaN layer 142e1, a second P—AlGaN layer 142e2 and a P—AlInGaN layer 144e. The amount of aluminum of the first P—AlGaN layer 142e1 is different from the amount of aluminum of the second P—AlGaN layer 142e2. A material of the first P—AlGaN layer 142e1 is preferably AlₓGa₁₋ₓN, and the x falls between 0.09˜0.2, and the material of the second P—AlGaN layer 142e2 is preferably Al_{y}Ga_{1-y}N, and the y falls between 0.01˜0.15. With the difference between the amount of the aluminum of the first P—AlGaN layer 142e1 and the amount of the aluminum of the second P—AlGaN layer 142e2, the light absorption can be prevented, and the problems of the epitaxial defect and the high resistance can be reduced simultaneously. The first P—AlGaN layer 142e1 is disposed between the second P—AlGaN layer 142e2 and the P—AlInGa layer 144e, and the P—AlInGa layer 144e directly contacts with the light emitting layer 130. The P—AlInGaN layer 144e can reduce the lattice mismatch between the first P—AlGaN layer 142e1 and the light emitting layer 130, and the stress during the growth of the LED structure 100e can be reduced.

FIG. 6 is a schematic cross-sectional view depicting a light emitting diode structure according to another embodiment of the present invention. Referring to FIG. 6, the LED structure 100f of the present embodiment is similar to the LED structure 100a of FIG. 1, while the main difference therebetween lies in that the LED structure 100f of the present embodiment further comprises a transparent conductive layer 170, wherein the transparent conductive layer 170 is disposed on the P-type semiconductor layer 140a, and the transparent conductive layer 170 is located between the P-type semiconductor layer 140a and the P-type electrode 160. The P-type semiconductor layer 140a can form a good ohmic contact by transparent conductive layer 170 and P-type electrode 160. Herein, a material of the transparent conductive layer 170 may be indium tin oxide (ITO), indium zinc oxide (IZO), zinc oxide (ZnO), indium tin zinc oxide (ITZO), aluminum zinc oxide (AZO), aluminum zinc oxide (AZO) or other proper transparent conductive materials.

In view of the above, since the thickness of the P—AlGaN layer is more than 85% the thickness of the P-type semiconductor layer according to the present invention, the near-ultraviolet light or the blue light emitted from the light emitting layer absorbed by the P-type semiconductor layer can be reduced. Therefore, the LED structure of the present invention can have better light emitting efficiency.

It will be apparent to those skilled in the art that various modifications and variations can be made to the structure of the disclosed embodiments without departing from the scope or spirit of the invention. In view of the foregoing, it is intended that the disclosure cover modifications and variations of this specification provided they fall within the scope of the following claims and their equivalents.

What is claimed is:

1. A light emitting diode structure, comprising:
a substrate;
a N-type semiconductor layer disposed on the substrate;
a light emitting layer adapted to emit a light with dominant wavelength between 365 nm and 490 nm and disposed on the N-type semiconductor layer; and
a P-type semiconductor layer disposed on the light emitting layer and comprising a P—AlGaN layer, wherein a thickness of the P—AlGaN layer is more than 85% a thickness of the P-type semiconductor layer.

2. The light emitting diode structure as recited in claim 1, wherein the P-type semiconductor layer is the P—AlGaN layer.

3. The light emitting diode structure as recited in claim 1, wherein the P-type semiconductor further comprises a P—GaN layer disposed on the P—AlGaN layer, and a thickness of the P—GaN layer is less than 15% the thickness of the P-type semiconductor layer.

4. The light emitting diode structure as recited in claim 1, wherein the P—AlGaN layer comprises a first P—AlGaN layer and a second P—AlGaN layer, and an amount of aluminum of the first P—AlGaN layer is different from an amount of aluminum of the second P—AlGaN layer.

5. The light emitting diode structure as recited in claim 4, wherein the first P—AlGaN layer is located between the second P—AlGaN layer and the light emitting layer, and the amount of the aluminum of the first P—AlGaN layer is greater than the amount of the aluminum of the second P—AlGaN layer.

6. The light emitting diode structure as recited in claim 5, wherein a material of the first P—AlGaN layer is AlₓGa₁₋ₓ N, and the x falls between 0.09˜0.2.

7. The light emitting diode structure as recited in claim 5, wherein a material of the second P—AlGaN layer is Al_{y}Ga_{1-y}N, and the y falls between 0.01˜0.15.

8. The light emitting diode structure as recited in claim 4, wherein a thickness of the second P—AlGaN layer is greater than a thickness of the first P—AlGaN layer.

9. The light emitting diode structure as recited in claim 4, wherein a P-type dopant concentration of the first P—AlGaN layer is greater a P-type dopant concentration of the second P—AlGaN layer.

10. The light emitting diode structure as recited in claim 1, wherein the P-type semiconductor layer further comprises a P—AlInGaN layer disposed between the P—AlGaN layer and the light emitting layer.

11. The light emitting diode structure as recited in claim 1, wherein the N-type semiconductor layer is a N—GaN layer.

12. The light emitting diode structure as recited in claim 1 further comprising:
a N-type electrode disposed on the N-type semiconductor layer uncovered by the light emitting layer and electrically connected to the N-type semiconductor layer; and
a P-type electrode disposed the P-type semiconductor layer and electrically connected to the P-type semiconductor layer.

13. The light emitting diode structure as recited in claim 1 further comprising:
a transparent conductive layer disposed on the P-type semiconductor layer.
